(19) United States
(12) Patent Application Publication
(10) Pub. No.: US 2007/0166464 A1
(43) Pub. Date: Jul. 19, 2007

(54) Process for preparing superhydrophobic surface compositions, surfaces obtained by said process and use of them

(76) Inventors: Kazim Acatay, Tuzla-Istanbul (TR); Mehmet Ali Gulgun, Tuzla-Istanbul (TR); Yusuf Ziya Menceloglu, Tuzla-Istanbul (TR)

Correspondence Address: LADAS & PARRY, 26 WEST 61ST STREET, NEW YORK, NY, 10023, US

(21) Appl. No.: 10/569,919

(22) PCT Filed: Sep. 2, 2003
(86) PCT No.: PCT/TR03/00067

§ 371 Date: Oct. 17, 2006

(51) Int. Cl. H01L 21/8238; B05D 3/12; B05D 1/02

(52) U.S. Cl. 427/346; 523/122; 427/421.1

(57) ABSTRACT

The present invention relates to a process for preparing super-hydrophobic surface compositions, to compositions obtained by said process and to the use of said compositions. The process comprises these steps of a) radical or condensation polymerisation of a reactive functional group containing monomer pair with an initiator in non-reactive solvent environment, and b) mixing the copolymer obtained in a) with a hydrocarbon/fluorinated/siloxane chemical agent having at least one end capped with reactive groups and a catalyst characterised in that it further comprises the step of c) electrospinning/electrospraying of the mixture obtained in b), and d) annealing and crosslinking of the electrospun/electrosprayed mixture.

The present invention relates to a process for preparing super-hydrophobic surface compositions and to compositions obtained by said process. More precisely the present invention relates to an electrospinning or electrospraying process for preparing super-hydrophobic surface compositions and to nanofabricated super-hydrophobic surfaces obtained by this process. The invention also relates to the use of the super-hydrophobic surfaces obtained.

The term of super-hydrophobicity is related with surface tension/energy. Surface tension/energy is an internal force due to an unbalance in molecular forces that occur when two different materials are brought into contact with each other forming an interface or boundary. At the liquid-surface interface, if the adhesive forces are stronger than the cohesive forces, the molecules of the liquid have a stronger attraction to the molecules of the solid surface than to each other and wetting of the surface occurs. If the adhesive forces are weaker, the liquid does not wet the surface of the solid.

Surface energy of a solid can be determined by Goniometry in that the contact angle of various liquids on a surface is measured. These contact angle values are related with surface energy by empirical or theoretical equations according to various theories. Water contact-angle on a solid surface larger than 140-160° represents a super-hydrophobic surface.

Generally, super-water repellent surfaces are created either by tailoring the surface chemistry and topography with various time consuming and complex techniques or by creating hydrophobic surface that is not solvent resistant.

Compositions for producing difficult to wet surfaces are given in EP-A-1.153.987. EP-A-1.238.717 relates to the geometric shaping of surfaces having a Lotus effect. EP-A-1.249.280 and EP-A-1.249.281 relate to self-cleaning surfaces with hydrophobic structures and process for making them. EP-A-1.249.467 and EP-A-1.249.468 relate to self-cleaning surfaces due to hydrophobic structure and process for the preparation thereof and EP-A-1.283.077 relates to obtaining a lotus effect by preventing microbial growth on self-cleaning surfaces.

As can be seen considerable scientific and industrial research activities are performed on development of super-hydrophobic, low surface energy, polymeric coating surfaces. But none of these techniques is particularly robust or long lasting, and can be controlled on a more substantial scale except in very clean environments.

It is an aim of the present invention to provide a method for making coatings in a short time and with a simple equipment requirement. It is also an aim of the present invention to provide coatings having ease and minimal cost of application. It is another aim of the present invention to provide coatings with good film forming properties having high surface area to volume ratio. It is another aim of the present invention to provide coatings with tuneable surface properties, such as hydrophobic, lypophobic, antibacterial etc. Finally it is an aim of the present invention to provide super-hydrophobic coatings.

The above aims have been achieved by Applicants invention.

The invention relates to a process for preparing super-hydrophobic surface compositions comprising the steps
a) radical or condensation polymerisation of a reactive functional group containing monomer pair with an initiator in non-reactive solvent environment, and
b) mixing the copolymer obtained in a) with a hydrocarbon/fluorinated/siloxane chemical agent having at least one end capped with reactive groups and a catalyst.
   characterised in that it further comprises the step of
c) electrospinning/electrospraying of the mixture obtained in b), and
d) annealing and crosslinking of the electrospun/electrosprayed mixture.

In step a) that the monomer pairs are radical or condensation polymerisable monomers and their combination and step growth polymerisable monomers where one of them contains fluoro/siloxane/hydrocarbon alkyl group and a reactive functional group chosen from the group comprising TMI/AN, TMI/Styrene, TMI/polymethylmethacrylate and perfluoro-alkyl acrylate/vinyl benzyl-dimethyl-cocoamonium chloride (VBDMCAC).

In step a) the initiator is a radical generating initiator or condensation polymerisation catalyst chosen from the group comprising azo initiators such as AIBN, peroxide initiators such as BPO, ammonium persulphate, sodium persulphate and T2EH. Again in step a) the non reactive solvent is preferably chosen from the group comprising dimethyl formamide (DMF), tetrahydro furan (THF), chloroform, methylene chloride, toluene, dichloromethane, ethanol, formic acid, dimethylacetamide, acetone.

In step b) the hydrocarbon/fluorinated/siloxane chemical agent has both ends capped with reactive groups such as hydroxyl, amine, carboxyl, isocyanate, thiol. Preferably the both end reactive group containing agent is chosen from the group comprising, (perfluoropolyether, PFPE) HOCH₂CF₂(OCF₂)ₙ(OCF₂CF₂)ₘCF₂CH₂OH, (siloxane diols) HO(Me₂Si—O)ₙH, (hydrocarbon diol) HO(CH₂)ₙOH, and (polyether diol) HO(CH₂CH₂O)ₙH.

Again in step b) the catalyst is chosen from the group containing stannous-2-ethyl hexanoate (T2EH), cobalt-2-ethyl hexanoate, dibutyltin dilaurate, etc.

In step c) a polymer solution or melt, held by surface tension at the end of a capillary, is subjected to a high electric field (Up to 20-30 kV). A jet of the solution ejected from the tip is charged and directed to a grounded collector, the solvent evaporates and a continuous, non-woven, ultra-thin (40-2000 nm in diameter) fibres and particles can be collected. Electrospraying process needs higher applied voltages and nanometer or micrometer range small, polymer solution droplets are transferred to the grounded screen.

The advantages of electro-spinning/spraying are its ability to make fibres/particles in the range of nanometers (one to two orders of magnitude smaller than the conventional fibres), high surface area to volume ratio, equipment requirement is simple and spinning time is much shorter than the conventional spinning.

Also, the material's bulk properties effect decreases in nanometer scale and the atomic properties becomes more effective. So, the material may show strange properties when compared with the bulk properties in nanometer diameter. By the aid of electro-spinning/spraying, tunable surface properties can emerge.

The invention also relates to super-hydrophobic surface compositions obtained by the above process and to the use of these super-hydrophobic surface compositions.

Said use can be in the prevention of adhesion of dirt and foreign materials to materials like antennas, windows, bio-reactors, solar cells, traffic indicators, public transports and animal cages.

Said use can also be in antifouling applications in human made marine vessels and buildings, haven appliances and oil-drilling platforms. Also said use can be in stain resistance of the materials in saunas, swimming-pools, bathrooms, kitchens, roofs, walls, facades, green-houses, garden fences, wood appliances.

Finally said use can be in multi-functional membranes, biomedical structural elements (scaffolding used in tissue engineering, wound dressing, drug delivery, artificial organs), protective shields in specialty fabrics, filter media for submicron particles in separation industry, composite reinforcement, and structures for nano-electric machines.

The accompanying drawings, which are included to provide a further understanding of the invention and are hereby incorporated in and constitute a part of this specification, illustrate embodiments of the invention and together with the specification serve to explain the principles of the invention.

In the drawings:

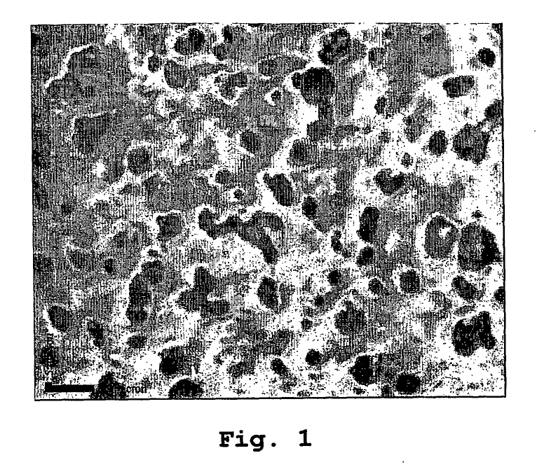

FIG. 1 is the scanning electron microscope image of electrospray film at 15 kV

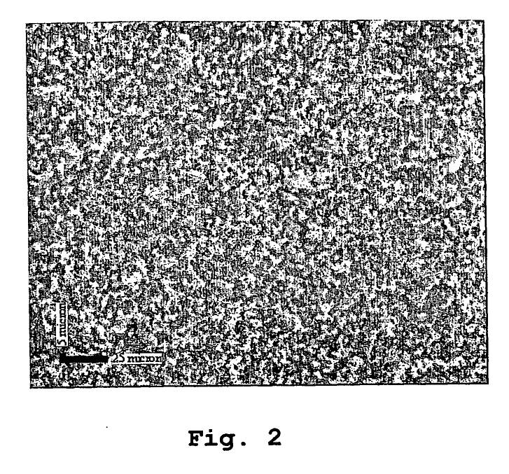

FIG. 2 is the scanning electron microscope image of electrospray film at 10 kV

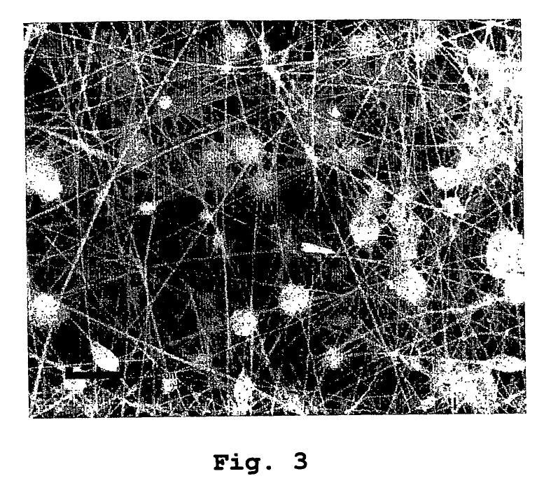

FIG. 3 is the scanning electron microscope image of electrospun film at 7 kV

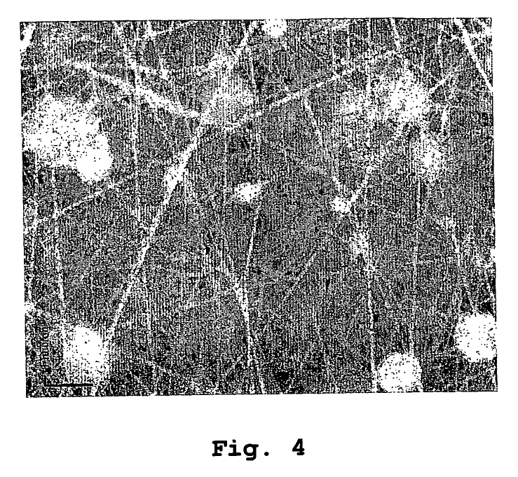

FIG. 4 shows an enlarged image of FIG. 3

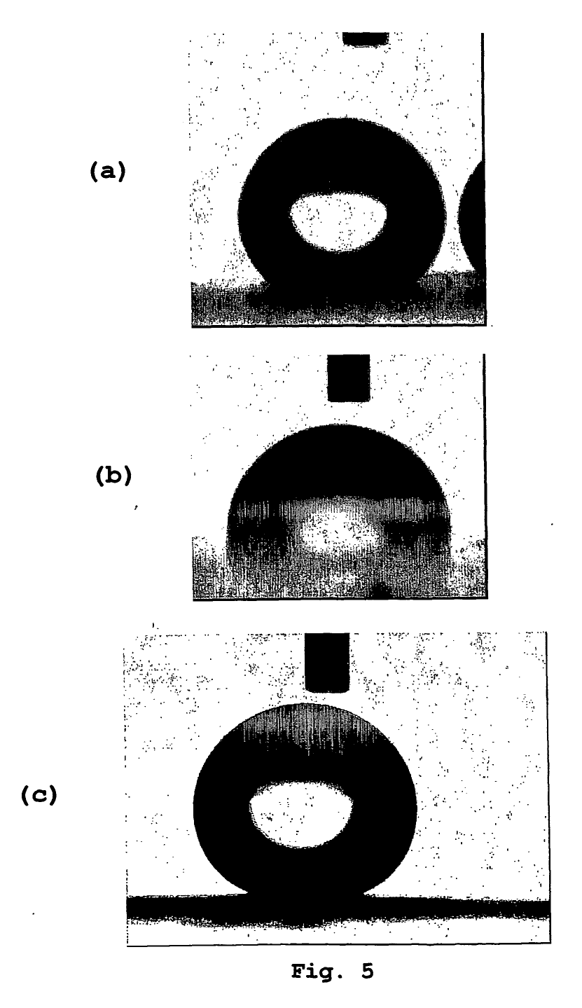

FIG. 5 shows contact angle photograph of water a) on a electrospun web of mixture, b) on a cast film of same mixture and c) on a condensation route polymerised sample

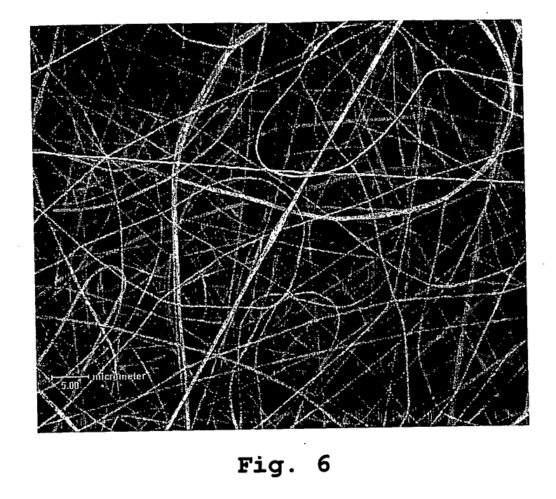

FIG. 6 shows the scanning electron image of an electrospun film obtained according to Example 2

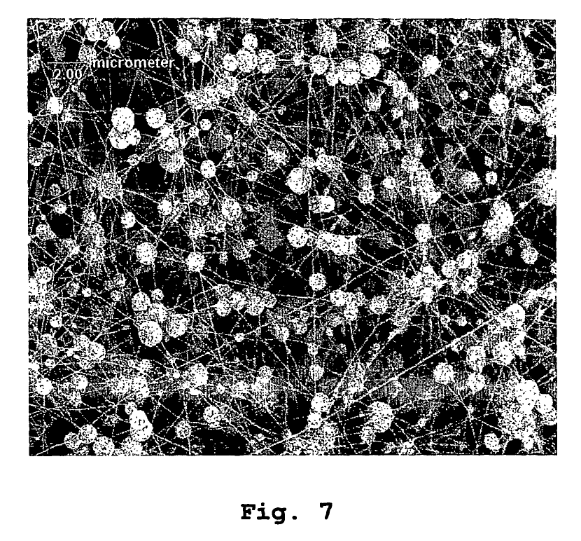

FIG. 7 shows the scanning electron image of an electrospun film obtained by fluorinated diol substitution in addition polymerisation with crosslinker route

It is to be understood that the foregoing general description and the following detailed description are exemplary and explanatory and are intended to provide further explanation of the invention as claimed.

The invention concerns an electrospinning/electrospraying processes for preparing super-hydrophobic surface compositions and to nanofabricated super-hydrophobic surfaces obtained. The surface of the perfluorinated/siloxane/hydrocarbon and cross-linked copolymeric resins shows after electro-spinning/spraying and annealing super-hydrophobic property.

The prepared coating material can be tailored to various conditions over a wide range of amphipilicy (chemically and topographically) and those properties can be adjusted or tuned without adversely affecting the stability, curability, or mechanical properties of the material.

For obtaining super-hydrophobicity, the solid surface is enhanced chemically by using fluorine/silicone containing moieties in the material. These materials exhibit low surface energy, low water absorptivity, stain resistance, high thermal stability, higher level of chemical inertness and excellent weatherability

Another point for chemical enhancement is segregation of fluorinated chemical moieties in a polymer or copolymer. By this segregation, a fluorine rich inter-layer between the bulk of the polymer and air is created by the aid of surface tension difference of the fluorinated and organic segments. This behaviour can be enhanced by heat annealing of the polymeric material.

Finally surface topography has a vital effect on wettability and self-cleaning behaviour of the material surface. The phenomenon called “Lotus-Effect” was discovered and published by Barthlott, W. and Neinhus, C., 1997, Purity of the sacred lotus, or escape from contamination in biological surfaces, Planta, 202: 1-8. It was also found that these surfaces are super-hydrophobic.

The basis of Lotus effect lies on the presence of many small sized bumps on the solid surface, so when a liquid drop or dirt is attached, the attractive force of the surface is so small that foreign substance cannot stay on it. If the surface is slightly slanted, because of this small contact area the droplets roll off under their own weight and collect the dirt on the tips of bumps and carry them. This is because the attractive force of the water molecules is stronger in total then the surface force, creating a self-cleaning surface.

Applicants' have surprisingly found that also by electro spinning/electro spraying process similar surface roughness and topography can be generated.

In the electro-spinning/spraying process, a polymer solution or melt, held by surface tension at the end of a capillary, is subjected to a high electric field (Up to 20-30 kV). Charge repulsion causes a force opposite to the surface tension at the tip. As the intensity of the potential field is increased, the surface of the solution at the capillary tip elongates to form a conical shape.

When the electric field reaches a critical value at which repulsive electrical forces overcome surface tension, a jet of the solution is ejected from the tip. This jet is charged and can be directed to a grounded collector.

As the jet travels through the air, the solvent evaporates and this brings thinner fibres. At the end, a continuous, non-woven, ultra-thin (40-2000 nm in diameter) fibres and particles can be collected on the grounded screen.

Electrospraying process needs higher applied voltages than electrospinning. Similar surface roughness as the electrospinning can be created. Instead of nanometer diametered nonwoven fibres, nanometer or micrometer range small, polymer solution droplets are transferred to the grounded screen.

TABLE 1
Surface energies and contact angles for water on several substrates.

| Substrate | Surface Energy | Contact Angle |
|---|---|---|
| PMMA | 41 | 74 |
| Nylon | 38 | 79 |
| Polyethylene | 33 | 96 |
| Polypropylene | 26 | 108 |
| Paraffin | 19 | 110 |
| Teflon | 18 | 112 |
| Clean Glass | 73 | 0 |
| Ordinary Glass | 70 | 20 |

In order that the invention may be more readily understood, reference is made to the following examples which are intended to illustrate the invention, but not restrict or limit whatsoever the scope thereof.

### EXAMPLES

### Example 1

### Addition Polymerization Route with Crosslinker

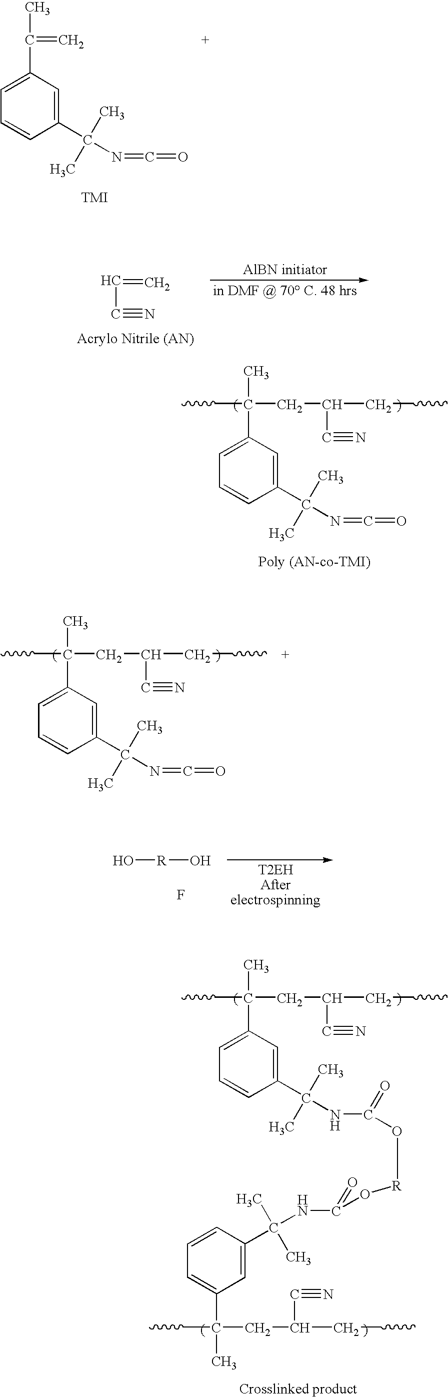 Materials

In the first reaction scheme:
The meta-Tetramethyl Xylene Isocyanate (TMI), also known as Isopropenyl dimethyl benzyl isocyanate, was supplied by Cytec and used in the reactions as received.
The second reactant needed, for the first reaction in the reaction scheme, Acrylo Nitrile (AN), was from Merck (00834) and stabilised with hydroquinone monomethyl ether. Acrylo Nitrile was purified by passing through alumina filled column and dried with anhydrous sodium sulfate before reaction.
For the same reaction, Azoisobutyronitrile (AIBN, Fluka-11630) was used as initiator and N,N-Dimethyl formamide (DMF, Riedel-15440) was used as solvent. Both were used as received.

In the second reaction in the reaction scheme,
Fluorolink-D® (a Perfluoropolyether, PFPE, supplied by Ausimont), a diol with 1000 gr/mol average equivalent weight, was used as fluorinated diol HOCH₂CF₂(OCF₂)n(OCF₂CF₂)ₘCF₂CH₂OH.
Tin (II) 2-ethylhexanoate (T2EH) was supplied from Aldrich (#28,717-2).
Instead of PFPE, ethylene glycol (Merck #822329) and
siloxane diol (40 000 gr/mol) containing trials had also been performed.

All chemicals were used as received.

Synthesis

1. Poly (AN-co-TMI)

In a 50 ml flask 25 ml DMF, 2.51 gr TMI, 6.67 gr AN and 3 mg initiator AIBN are added. Head of the flask is sealed with Aldrich brand Natural Rubber Septa. The solution is shaked for 5 minutes. Than, the content is placed into 70° C. oven and kept there for 48 hours for radical polymerisation of monomers in solution. The flask content is stored in −20° C. refrigerator when not used.

In order to check the conversion of the reactants to polymer 1.65 gr DMF poly (AN-co-TMI) mixture is added in 15 ml methanol and mixed for 10 minutes. The precipitated solid polymer is dried and weighed. The conversion of the reaction is approximately 50-60%.

2. a Fluorine Containing Poly (AN-co-TMI)

1.62 gr poly (AN-co-TMI) in DMF is transferred into a separate flask and 0.03 gr PFPE is added. To adjust the viscosity to 200-1200 cp range, 1.05 gr DMF is also added. After the addition of 3 droplets of T2EH, the content of the flask is mixed for 2 minutes and transferred into glass Pasteur pipettes for electro-spinning purpose.

2.b Hydrocarbon Containing Poly (AN-co-TMI)

2.09 gr poly (AN-co-TMI) in DMF is transferred into a separate flask and 0.06 gr Ethylene Glycol is added. To adjust the viscosity to 200-1200 cp range, 0.5340 gr DMF is also added. After the addition of 3 droplets of T2EH, the content of the flask is mixed for 2 minutes and transferred into glass Pasteur pipettes for electro-spinning purpose.

2.c. Siloxane Containing Poly (AN-co-TMI

1.18 gr poly (AN-co-TMI) in DMF is transferred into a separate flask and 0.27 gr siloxane diol is added. To adjust the viscosity to 200-1200 cp range, 1.05 gr DMF is also added. After the addition of 3 droplets of T2EH, the content of the flask is mixed for 2 minutes and transferred into glass Pasteur pipettes for electro-spinning purpose.

Electrospinning

Electrospinning of poly (AN-co-TMI) plus Fluorolink-D® (and Ethylene Glycol and Siloxane diol) mixture is performed, at room temperature conditions, in an apparatus similar as given in Demir M M et al. 2002, Electro-spinning of polyurethane fibres, Polymer. The Pasteur pipette is a glass having 1 mm tip opening, the metal probe is a copper wire that is directly connected to power supply, which is a 50 kV CPS Technologies Model 2594.

The grounded collector used was a 20 cm×20 cm flat aluminium foil that acted as electrically conductive surface, connected to ground by the aid of a conductive wire. The tip to ground distance was 10 cm. The electro-spinning voltage was 7-20 kV.

Annealing and Casting

After electro-spinning, the aluminium foil was:
a) annealed at 70° C. for at least 18 hours under nitrogen atmosphere for complete crosslinking and electrospun, crosslinked and annealed film was obtained.
b) In order to compare the difference between electrospun film and bulk film, the remaining poly (AN-co-TMI) plus PFPE diol mixture is applied over glass lamellas as a thin layer of film and annealed at 70° C. Cast and annealed films are obtained.
   Goniometry Studies

The contact angle measurements of the electrospun and cast films are performed by DSA 10 Mk 2 Goniometry of Krüss GmbH with DSA 1 v.1.7 software.

In the contact angle measurements of the electrospun films on aluminium foil; double-side adhesive coated tape is put onto a glass lamella and the aluminium foil covered with film is cut approximately 10 cm² and placed on the adhesive tape.

Contact angle measurements of the electrospun films and cast films on lamellas (with annealing and without annealing) are done without any further treatment. During contact angle measurements, at least six static water droplets, each at the same volume, are studied for the films. The water used for measurements was ultra-pure grade and fresh.

The contact angle (CA) measurements were performed by water and the results are presented at Table 2.

TABLE 2
Contact angle measurement results.

| Sample | Description | Water CA(°) |
|---|---|---|
| Teflon Film | Commercial | 107.20 ± 2.44 |
| Fluorinated 13.3% | Electrospun Web at FIG. 3 &4 | 143.20 ± 3.56 |
| Fluorinated 13.3% | Cast film of FIG. 3&4 mixture | 88 ± 4.84 |
| Fluorinate 13.3% | Electrospun Web at FIG. 2 | 141.45 |
| Fluorinated with 9.3 | Cast Film - Normal | 102.3 ± 3.39 |
| w % | | |
| Fluorolink-D ® | Cast Film - Annealed | 106 ± 0.52 |
| | Electrospun - Normal | 149.2 ± 0.85 |
| | Electrospun - Annealed | 154.2 ± 1.62 |
| Ethylene Glycol as | Electrospun - Normal | 140.1 ± 1.02 |
| diol | Electrospun - Annealed | 144.8 ± 0.79 |
| Siloxane diol with | Electrospun - Normal | 144.9 ± 2.74 |
| 40 000 gr/mol | Electrospun - Annealed | 146.6 ± 3.86 |

The measured contact angle values for Teflon are in good agreement with the literature values, which proves the method's applicability. Also, from Table 2, it can be seen that, there was a huge contact angle value difference between same composition mixture's electrospun-annealed film (154°) and cast film (100°).

Other Characterisation Instruments

The Scanning electron microscope (SEM) images of poly (AN-co-TMI)+Fluoro-link D at several voltages are presented at FIGS. 1 to 4. The apparatus used was a Jeol 840A Model Scanning Electron Microscope. For SEM measurement purposes electrospun covered aluminium foils were cut 1 cm×1 cm. The concentration of the resin mixtures of electrospuns in FIGS. 2, 3 and 4 were approximately same.

As the spinning voltage decreases, the fibre formation becomes distinct. As the voltage decreases, the attractive force by electrical field is balanced (no excess pull), so stable fibres form from tip to collector and they have found enough time to evaporate solvent.

Also, Applicants have tested if the electrospun product dissolve in DMF or Tetrahydrofuran (TH F), the reaction media preferred for the polymerisation reaction. 10 ml DMF and 10 ml THF are added respectively in 2 flasks and approximately 100 mg of electrospun film is added to each flask, that is shaked for 1 hour and left for 1 week. No dissolution of the cured electro-spinning product was observed in either of the reaction media, DMF and THF.

Effect of Fluorolink-D® Concentration to CA

The optimum value of Fluorolink-D® is important due to economical reasons for industry. So, 1 w % to 100 w % (relative to solid content in the poly (AN-co-TMI) solution) of Fluorolink-D® are added to the electro-spinning solution.

Also, for each concentration, mixtures are cast filmed on two lamellas. One was annealed, but the other was not to compare the effect of annealing even at cast films. The results are presented at Table 3.

TABLE 3
Effect of concentration of Fluorolink-D ® to CA.

| | Fluoro-link concentration | | | | | |
|---|---|---|---|---|---|---|
| | 6.4 w % | 9.3 w % | 22.5 w % | 33.9 w % | 56 w % | 100 w % |
| Cast Film | 107.2 ± 5.03 | P12 106 ± 0.52 | — | 101.9 ± 0.72 | 101.9 ± 1 | 92.8 ± 2.19 |
| Annealed | | | | | | |
| Cast Film | 96.4 ± 1.37 | 102.3 ± 3.39 | — | 94.2 ± 2.88 | 103.8 ± 3.95 | 100.1 ± 7.26 |
| Normal | | | | | | |
| E-spun Film | 146.6 ± 1.92 | 154.2 ± 1.62 | 146.8 ± 2.11 | 142 ± 3.13 | 143.2 ± 1.58 | 143.9 ± 3.88 |
| Annealed | | | | | | |

### Example 2

### Addition Polymerization Route without Crosslinking Reaction

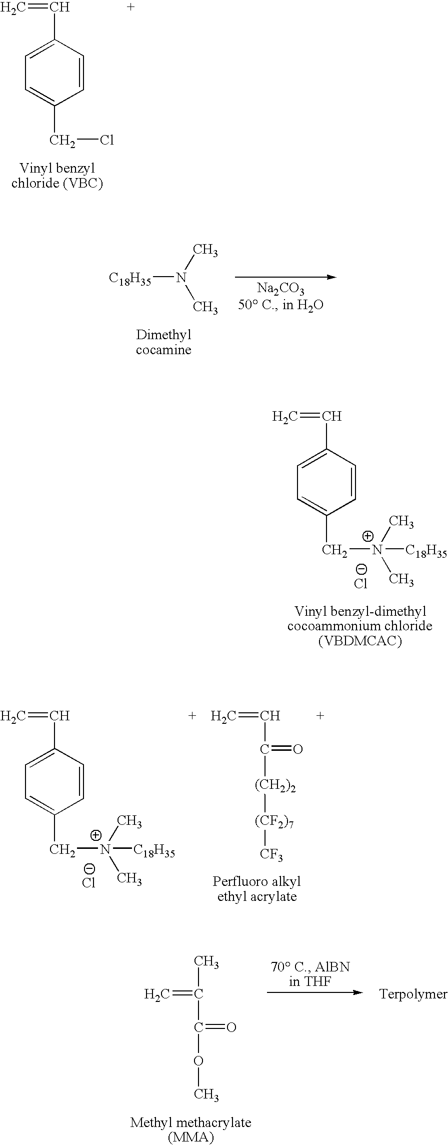 Materials

The chemicals used are as follows:
Vinyl Benzyl Chloride (VBC) is from Fluka (#94907),
Dimethylcocoamine is industrial grade,
Sodium carbonate (Na₂CO₃) is supplied from Fluka (#71352)
Perfluoroalkyl ethyl acrylate is Fluowet from Clariant,
Methylmethacrylate (MMA) is from Fluka (#71351),
AIBN (Fluka-11630) is used as the radical initiator for terpolymer synthesis reaction
THF is Analytical Reagent grade of LabKim.

All chemicals were used as received.

Synthesis

Vinyl benzyl-dimethyl cocoammonium chloride (VBDMCAC)

The synthesis of VBDMCAC is carried in a 50 ml round bottom flask. 16.2 gr of dimethylcocamine, 12.6 gr of distilled water and 0.3 gr of Na₂CO₃ is mixed. Than, 8.6 gr of VBC is added while agitating the mixture. The reaction is carried at 50° C. under atmospheric pressure and continuous agitation for 2 hours.

Polymerization for Terpolymer

In a 50 ml flask, 1.25 gr perfluoroalkyl ethyl acrylate, 2.23 gr MMA, 0.11 gr VBDMCAC mixture and 0.004 gr AIBN is added into 5.4 gr tetrahydrofuran (THF) solvent. This mixture is degassed for 15 minutes by bubbling with nitrogen gas. The radical polymerization in solution is carried at 70° C. for 24 hours. The product is precipitated in 150 ml of industrial grade n-hexane, filtered and dried.

Electrospinning

Electrospinning is carried in room environment. 0.2 gr of terpolymer is dissolved in 0.5 gr THF and 0.5 gr DMF containing solution. Than the mixture is poured to Pasteur pipette and electrospun with the aid of high voltage generator. The product is collected onto 20 cm×20 cm flat aluminium collector. The tip to ground distance is 10 cm and the electrospinning voltage is 12 kV.

Goniometry Study

The contact-angle measurement of the electrospun film is performed by DSA 10 Mk 2 Goniometry of Krüss GmbH with DSA 1 v.1.7 software. Not annealed was 159.2±2.4. In the contact angle measurements of the electrospun films on aluminium foil; double-side adhesive coated tape is put onto a glass lamella and the aluminium foil covered with film is cut approximately 10 cm² and placed on the adhesive tape. During contact angle measurements, at least six static water droplets, each at the same volume, are studied for the films. The water used for measurements was ultra-pure grade and fresh.

### Example 3

### Condensation Polymerization Route

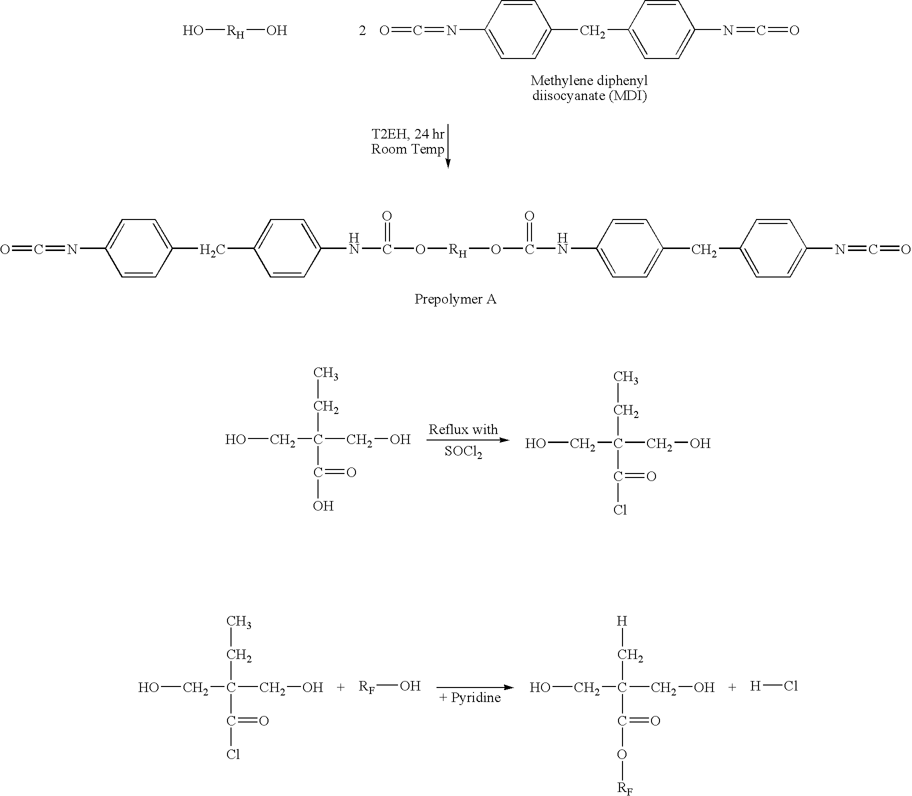 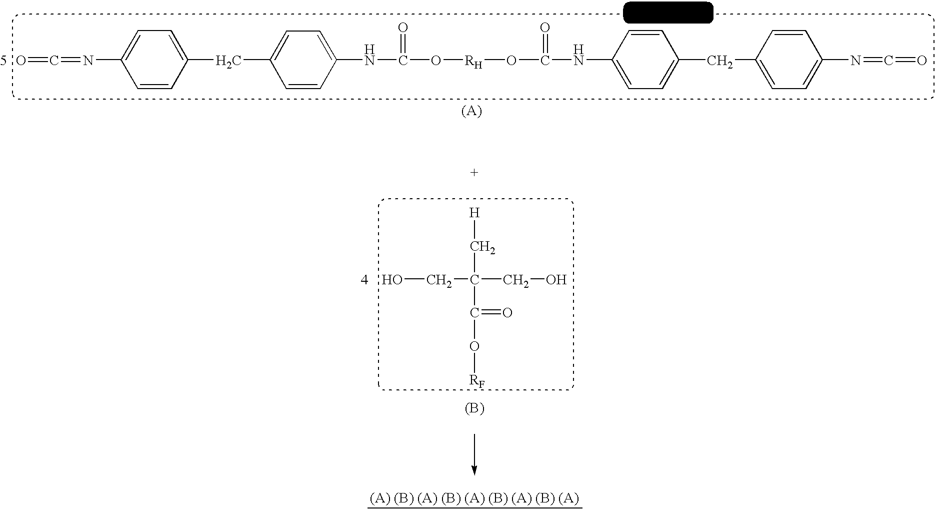 Materials

The chemicals used are as follows:
HO—R_{H}—OH is Polyethylene Glycol (PEG 4000) with a molecular weight of 4000 gr/mol from Merck (#07490),
Methylene diphenyl diisocyanate (MDI, C₁₅H₁₀N₂O₂) is from Acros (#41428),
Tin (II) 2-ethylhexanoate (T2EH) is supplied from Aldrich (#28,717-2),
Dimethylol butanoic acid (DMBA, C₆H₁₂O₄) is from Marubeni Corporation,
R_{F}—OH is perfluoroalkyl ethanol (PFAE, Fluowet® EA 600) from Clariant,
Thionyl chloride is from Merck (#808154) and
Pyridine is from LabScan (#G4544).

All chemicals were used as received.

Synthesis

Prepolymer A

In a 50 ml round bottom flask, 30 ml toluene solvent, 1 gr MDI and 8 gr PEG 4000 are added. 6-7 droplets of T2EH are also added to the flask as reaction catalyst. During the reaction, the head of the flask is covered with Rubber Septa, the mixture is agitated and kept under nitrogen atmosphere. The reaction is carried out for 24 hours at room temperature.

Prepolymer B

Prepolymer B is synthesized in two steps. First, in a 50 ml flask 7.4 gr of DMBA is refluxed with 30 ml Thionyl Chloride overnight and than, the chlorinated DMBA is purified by evaporation. In the second step, 3.33 gr of chlorinated DMBA is reacted with 7.4 gr of Fluowet® (PFAE) in 30 ml Toluene. As acid scavenger 6-7 drops of pyridine is added and the reaction is carried for 3 hours at room temperature. The product is filtered to remove Pyridine.HCl complex and Prepolymer B solution.

Polymerization

The required amount of Prepolymer A and Prepolymer B solutions for polymerization is calculated by determination of reactive groups with the titration method. In a 50 ml flask, Prepolymer A solution (29.3 ml) and Prepolymer B solution (2.28 ml) are mixed. As catalyst 8-9 droplets of T2EH is added. The reaction is carried at 80° C. for 48 hours. After the reaction is complete, the reaction mixture is poured into 300 ml of n-hexane and the product is precipitated. The precipitate is filtered with filter paper and dried in vacuum oven at room temperature for 48 hours.

Electrospinning

Electrospinning of polycondensation reaction product is carried at room temperature. 0.5 gr of condensation polymer is dissolved in 2.1 ml of DMF. Than the mixture is poured to Pasteur pipette and electrospun with the aid of high voltage generator. The product is collected on the grounded collector.

The grounded collector used is a 20 cm×20 cm flat aluminium foil that acted as electrically conductive surface, connected to ground by the aid of a conductive wire. The tip to ground distance was 15 cm. The electro-spinning voltage was 8-15 kV.

Annealing

After electro-spinning, the aluminium foil was annealed at 70° C. for at least 18 hours under nitrogen atmosphere for complete crosslinking. An electrospun, crosslinked and annealed film was obtained.

Goniometry Studies

The contact-angle measurement of the electrospun film is performed by DSA 10 Mk 2 Goniometry of Krüss GmbH with DSA 1 v.1.7 software.

In the contact angle measurements of the electrospun films on aluminium foil; double-side adhesive coated tape is put onto a glass lamella and the aluminium foil covered with film is cut approximately 10 cm² and placed on the adhesive tape.

### INDUSTRIAL APPLICATION

This physical phenomenon is an important property of materials mostly at printing industry, painting industry, membrane-manufacturing industry, lubricant industry or textile industry. So, determination and regulation of this physical property is crucial for the performance of many materials in their application fields.

Some implantation areas of super-hydrophobic surfaces are for example the prevention of adhesion of dirt and foreign materials to the materials. It can be used in antennas, bio-reactors, solar cells, traffic indicators, public transports, animal cages, etc.

One other application may be stain resistance of the materials. It can be used in saunas, swimming-pools, bathrooms, kitchens, roofs, walls, facades, green-houses, garden fences, wood appliances, etc.

One further application may be against the sticking of marine organisms and plants to the marine constructions, because if even the water cannot wet the surface, how can the marine organisms can stick on it. Antifouling applications may be used in human made marine vessels and buildings, haven appliances, oil-drilling platforms, etc.

Other application areas of electrospun fibres are multi-functional membranes, biomedical structural elements (scaffolding used in tissue engineering, wound dressing, drug delivery, artificial organs), protective shields in specialty fabrics, filter media for submicron particles in separation industry, composite reinforcement, and structures for nano-electric machines.

The terms and expressions which have been employed are used as terms of description and not of limitations, and there is no intention in the use of such terms or expressions of excluding any equivalents of the features shown and described as portions thereof. It will be obvious to those skilled in the art that various changes may be made without departing from the scope of the invention which is not be considered limited to what is described in the specification.

1. A process for preparing super-hydrophobic surface compositions comprising the steps
a) radical or condensation polymerisation of a reactive functional group containing monomer pair with an initiator in non-reactive solvent environment, and
b) mixing the copolymer obtained in a) with a hydrocarbon/fluorinated/sifoxane chemical agent having at least one end capped with reactive groups and a catalyst
characterised in that it further comprises the step of
c) electrospinning/electrospraying of the mixture obtained in b), and
d) annealing and crosslinking of the electrospun/electrosprayed mixture.

2. Process according to claim 1, characterised in step a) that the monomer pairs are radical or condensation polymerisable monomers and their combination and step growth polymerisable monomers where one of them contains fluoro/siloxane/hydrocarbon alkyl group and a reactive functional group chosen from the group comprising TMI/AN, TMI/Styrene, TMI/polymethylmethacrylate, and perfluoro-alkyl acrylate/vinylbenzyl-dimethyl-cocoamonium chloride (VBDMCAC).

3. Process according to claim 1, characterised in that in step a) the inert environment is a non reactive solvent chosen from the group comprising dimethyl formamide (DMF), tetrahydro furane (THF), chloroform, methylene chloride, toluene, dichloromethane, ethanol, formic acid, dimethylacetamide, acetone.

4. Process according to claim 1, characterised in that in step a) the initiator is a radical generating initiator or condensation polymerisation catalyst chosen from the group comprising azo initiators, peroxide initiators, ammonium persulphate, sodiumpersulphate and stannous-2-ethyl hexanoate (T2EH), cobalt-2-ethyl hexanoate, dibutyltin dilaurate.

5. Process according to claim 1, characterised in that in step b) the hydrocarbon/fluorinated/siloxane chemical agent having both ends capped with reactive groups such as hydroxyl, amine, carboxyl, isocyanate and thiol is a diol containing agent chosen between fluorinated diols, siloxane diols and hydrocarbon diols, preferably chosen from the group comprising (perfluoropolyether, PFPE) HOCH₂CF₂(OCF₂)ₙ(OCF₂CF₂)ₘCF2CH2OH, (siloxane diols) HO(Me₂Si—O)ₙH, (hydrocarbon diol) HO(CH₂)ₙOH, and (polyether diol) HO(CH₂CH₂O)ₙH.

6. Process according to claim 1, characterised in that in step b) the catalyst is chosen from organometallic catalysts comprising stannous-2-ethyl hexanoate (T2EH), cobalt-2-ethyl hexanoate, dibutyltin dilaurate.

7. Process according to claim 1, characterised in that in step c) the mixtures are electrospun/sprayed at 5-35 kV and 5-25 cm tip distance.

8. Process according to claim 1, characterised in that in step d) the electrospun/sprayed mats are annealed above the glass transition temperature.

9. Super-hydrophobic surface compositions obtained by a process according to claim 1, characterised in that their water contact-angle at least 140°.

10. Use of the super-hydrophobic surface compositions according to claim 9, in the prevention of adhesion of dirt and foreign materials to materials like antennas, windows, bio-reactors, solar cells, traffic indicators, public transports and animal cages.

11. Use of the super-hydrophobic surface compositions according to claim 9, in antifouling applications in human made marine vessels and buildings, haven appliances and oil-drilling platforms.

12. Use of the super-hydrophobic surface compositions according to claim 9, in stain resistance of the materials in saunas, swimming-pools, bathrooms, kitchens, roofs, walls, facades, green-houses, garden fences, wood appliances.

13. Use of the super-hydrophobic surface compositions according to claim 9, in multi-functional membranes, biomedical structural elements (scaffolding used in tissue engineering, wound dressing, drug delivery, artificial organs), protective shields in specialty fabrics, filter media for submicron particles in separation industry, composite reinforcement, and structures for nano-electric machines.
